(19) United States
(12) Patent Application Publication
(10) Pub. No.: US 2010/0254103 A1
(43) Pub. Date: Oct. 7, 2010

(54) ELECTRONIC CIRCUIT UNIT

(76) Inventor: Norihito Okada, Niigata-Ken (JP)

Correspondence Address: BRINKS HOFER GILSON & LIONE, P.O. BOX 10395, CHICAGO, IL, 60610, US

(21) Appl. No.: 12/730,716

(22) Filed: Mar. 24, 2010

(30) Foreign Application Priority Data
Apr. 6, 2009 (JP) 2009-092240

(51) Int. Cl. H05K 7/02

(52) U.S. Cl. 361/753; 361/760

(57) ABSTRACT

An electronic circuit unit electrically connected to a motherboard via a terminal soldered on a lower surface of a circuit board is provided, wherein the terminal has a bridge connection portion disposed on an upper surface of the circuit board, a first lead portion extending downwardly from one end of the bridge connection portion so as to be inserted through a first through-hole of the circuit board, and a second lead portion extending downwardly longer than the first lead portion from the other end of the bridge connection portion so as to be inserted through a second through-hole of the circuit board, the terminal having a bent form, and wherein the first lead portion is soldered on the lower surface of the circuit board, and the second lead portion is inserted into a terminal installation hole of the motherboard when the electronic circuit unit is mounted on the motherboard.

### CROSS REFERENCE TO RELATED APPLICATION

The present invention contains subject matter related to and claims priority to Japanese Patent Application JP 2009-092240 filed in the Japanese Patent Office on Apr. 6, 2009, the entire contents of which is incorporated herein by reference.

### BACKGROUND

1. Technical Field

The present disclosure relates to an electronic circuit unit properly used as, for example, a television set tuner and so on, and more particularly, to an electronic circuit unit on which terminals for use in external circuit connection are soldered on a lower surface of a circuit board.

2. Related Art

An electronic circuit unit such as a television set tuner mounted on a motherboard, sometimes has a group of relatively long terminals which are inserted in terminal installation holes provided in the motherboard. Generally, theses terminals are soldered on a wire pattern on a circuit board of the electronic circuit unit so as to be arranged in a row along one edge of the circuit board. When the electronic circuit unit is mounted on the motherboard, the lower end portion of each terminal is soldered on an external circuit of the motherboard side (for example, see JP-A-2002-009469).

The circuit board used in this electronic circuit unit is formed by soldering various electronic components or terminals on a predetermined wire pattern. Of these, a one-sided board, in which a soldering portion is not provided on an upper surface of the circuit board but is integrated only on its lower surface, can be manufactured at a low cost, and thus it is widely adopted.

However, in an electronic circuit unit having a relatively long terminal for use in external circuit connection, when this terminal is soldered on the wire pattern on the lower surface of the circuit board, a cream solder is applied on a land portion (soldering portion) of the wire pattern, a terminal is inserted through a through-hole adjacent to this land portion, and, in this state, it is transferred to a reflow furnace so as to be heated, whereby the cream solder is melted and attached to the terminal. However, when the terminal is inserted through the through-hole, the cream solder is attached to the lower end portion of the terminal, or the cream solder melted by the heating in the reflow furnace is flowed to the lower end side of the terminal. Therefore, when the solder is attached to the lower end portion of the terminal after the completion of the reflow soldering step, there is a problem that the solder has to be removed by a manual work or the like. In addition, if a large amount of solder is attached to the lower end portion of the terminal with a long size, there is a problem that an intensity of the terminal needed to be attached to the circuit board is insufficient. Also, when the solder is attached to the lower portion of the terminal for use in external circuit connection, it is difficult to insert this terminal into the terminal installation hole of the motherboard, and thereby the electronic circuit unit may be poorly mounted.

### SUMMARY

According to an embodiment of the present invention, an electronic circuit unit electrically connected to a motherboard via terminals soldered on a lower surface of a circuit board is provided. The terminals each have a bridge connection portion disposed on an upper surface of the circuit board, a first lead portion extending downwardly from one end of the bridge connection portion so as to be inserted through a first through-hole of the circuit board, and a second lead portion extending downwardly longer than the first lead portion from the other end of the bridge connection portion so as to be inserted through a second through-hole of the circuit board, the terminal having a bent form, The first lead portion is soldered on the lower surface of the circuit board, and the second lead portion is inserted into a terminal installation hole of the motherboard when the electronic circuit unit is mounted on the motherboard.

The electronic circuit unit configured as above may include the first and second lead portions which have a length different from each other by substantially parallel extension of the terminal for use in external circuit connection, and when this terminal is installed in the circuit board, the short-sized first lead portion can be reliably soldered in the associated land portion of the wire pattern provided on the lower surface of the circuit board. Therefore, it is not necessary to attach the solder to the long-sized second lead portion spaced apart from the first lead portion. Thereby, when the electronic circuit unit is mounted on the motherboard, the long-sized second lead portion of the terminal can be easily inserted into a terminal installation hole of the motherboard.

### BRIEF DESCRIPTION OF THE DRAWINGS

FIG. 1 is a view illustrating a terminal structure of an electronic circuit unit according to an embodiment of the invention;

FIG. 2 is a perspective view illustrating a terminal group of the electronic circuit unit;

FIG. 3 is a perspective view illustrating a state where the terminal group is installed on a circuit board of the electronic circuit unit;

FIG. 4 is a perspective view illustrating a state where a shield frame body is installed on the circuit board;

FIG. 5 is a perspective view illustrating a state where a lower cover is installed on the shield frame body; and

FIG. 6 is a view illustrating an appearance of the electronic circuit unit.

### DESCRIPTION OF EXEMPLARY EMBODIMENTS

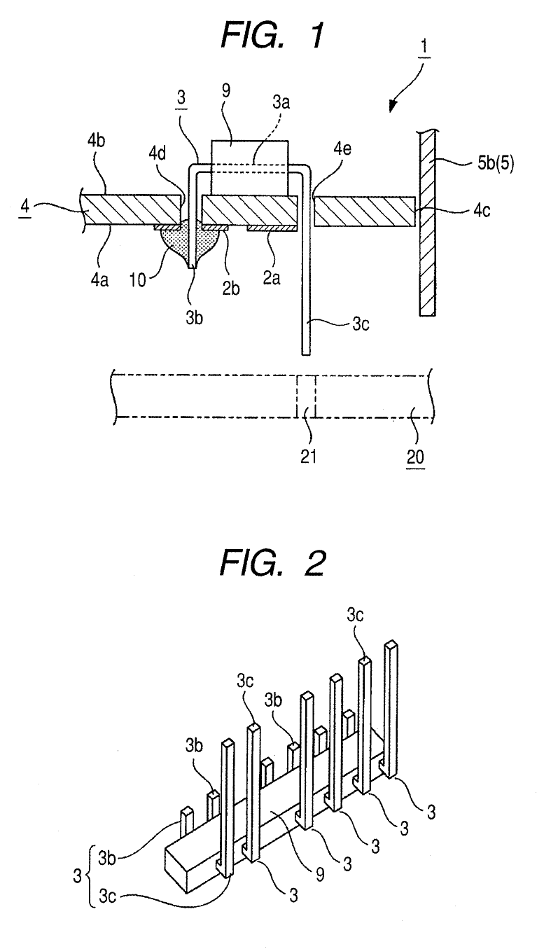

An electronic circuit unit according to an embodiment of the invention will now be described with reference to FIGS. 1 to 6. This electronic circuit unit 1 is a television set tuner, which is mainly constituted by a circuit board 4 on which a wire pattern 2 or a terminal 3 or the like is disposed, a shield frame body 5 which contains and supports the circuit board 4, an F type connector 6 which protrudes outwardly from one side plate 5a of the shield frame body 5, and an upper cover 7 and a lower cover 8 which cover an upper opening and a lower opening of the shield frame body 5, respectively.

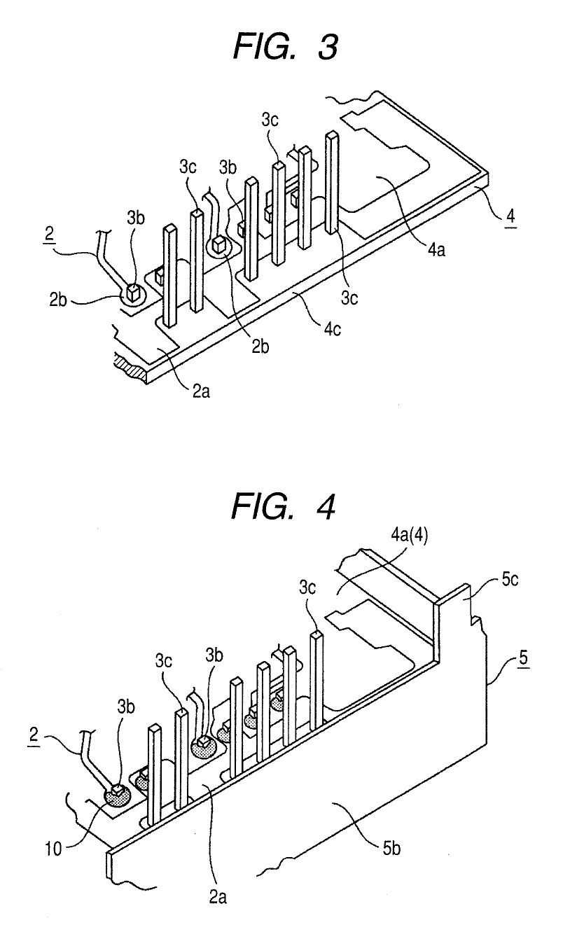

The circuit board 4 is a one-sided board on which a tuner circuit is formed, and has the wire pattern 2 including a ground pattern 2a and formed on its lower surface 4a. A plurality of electronic components (not shown) are disposed on the upper surface 4b of the circuit board 4, and these electronic components are soldered on the wire pattern 2 on the lower surface 4a side of the circuit board 4. In addition, a plurality of terminals 3 for use in external circuit connection is arranged in a row along one edge 4c of the circuit board 4. As described later, each terminal 3 has a first lead portion 3b which is short and a second lead portion 3c which is long. In order to correspond thereto, for each terminal 3, a first through-hole 4d for allowing first lead portion 3b to be inserted through and a second through-hole 4e for allowing the second lead portion 3c to be inserted through in the vicinity of the one edge 4c are provided on the circuit board 4 (see FIG. 1). A land portion 2b of the wire pattern 2 is formed in the vicinity of the first through-hole 4d on the lower surface 4a of the circuit board 4, and the first lead portion 3b is soldered in this land portion 2b. Also, the ground pattern 2a is adjacently disposed near the second through-hole 4e. The reference numeral 10 denotes a solder in FIGS. 1 and 4, whereas the solder is not shown in FIG. 3.

Each terminal 3 has a bridge connection portion 3a which is buried in a connection body 9 made of synthetic resins and is placed on the upper surface 4b side of the circuit board 4, the short-sized first lead portion 3b which extends downwardly from one end of the bridge connection portion 3a so as to be bent substantially perpendicularly, and the long-sized second lead portion 3c which extends downwardly from the other end of the bridge connection portion 3a so as to be bent substantially perpendicularly. Thus, each terminal 3 has a bent form. The first lead portion 3b slightly protrudes toward the lower surface 4a through the first through-hole 4d from the upper surface 4b of the circuit board 4, and this protrusion is soldered in the associated land portion 2b of the wire pattern 2. Further, the second lead portion 3c protrudes greatly toward the lower surface 4a through the second through-hole 4e from the upper surface 4b of the circuit board 4, and thereby a lower end portion of this protrusion is inserted into a terminal installation hole 21 (see FIG. 1) of a motherboard 20 so as to be soldered on an external circuit (not shown).

The second through-hole 4e for use in the second lead portion 3c is provided in the vicinity of the one edge 4c of the circuit board 4, so the terminal 3 for use in external circuit connection can make a distance between the second lead portion 3c and an electronic component of the motherboard 20 side shorter. Thereby, it is possible to suppress attenuation of a high frequency signal.

The bridge connection portion 3a of each terminal 3 is formed with the connection body 9 as a single body by an insert formation method in which the bridge connection portion is disposed in a formation molding of the connection body 9. For this reason, as shown in FIG. 2, the bridge connection portions 3a are connected to each other by the connection body 9 while the plurality of terminals 3 are arranged in a row so as to keep a predetermined position relationship therebetween.

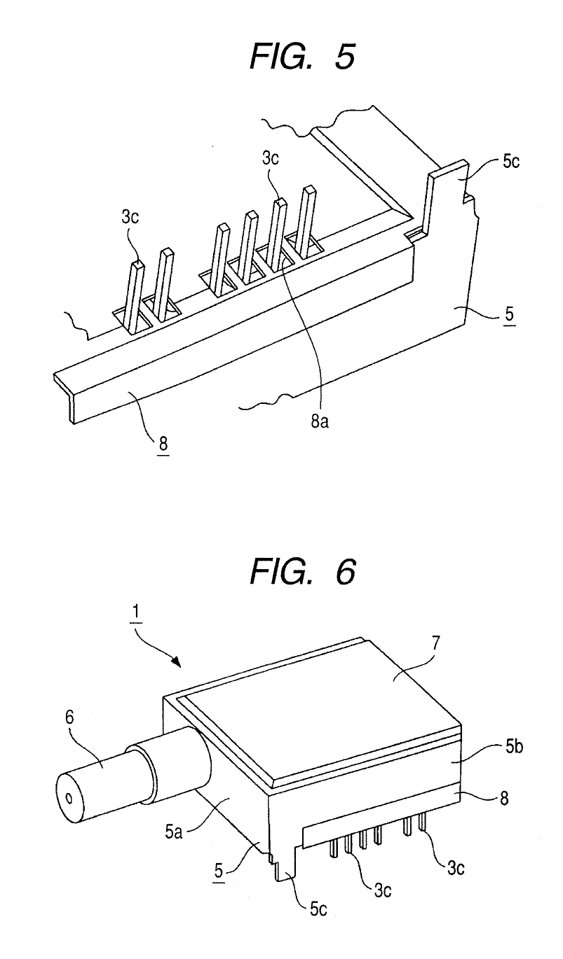

The shield frame body 5 is a metal plate which is installed in order to surround the circuit board 4, and is electrically connected to the ground pattern 2a while supporting an outer circumference of the circuit board 4. As shown in FIG. 6, the F type connector 6, which receives an antenna signal, is fixed to one lateral plate 5a of the shield frame body 5 by a caulking or a soldering, and a core line connection portion (not shown) inside this F type connector 6 is electrically connected to the wire pattern 2 of the circuit board 4. Further, as shown in FIGS. 1 and 4, the other lateral plate 5b of the shield frame body 5 is placed near the second lead portion 3c of each terminal 3 for use in external circuit connection, and the second through-hole 4e for use in the second lead portion 3c provided on the circuit board 4 is surrounded by this lateral plate 5b and the ground pattern 2a. A bridge piece 5c is disposed drooping at a corner of the shield frame body 5, and this bridge piece 5c is installed in the motherboard 20. The upper opening of the shield frame body 5 is covered by the upper cover 7, and the lower opening of the shield frame body 5 is covered by the lower cover 8, and thereby the circuit board 4 is hardly influenced by external noises since it is almost completely shielded electrically and magnetically. Also, as shown in FIG. 5, a release hole 8a is disposed in the lower cover 8 in order to allow the second lead portion 3c to be inserted loosely.

In the electronic circuit unit 1 having this configuration, when the terminals 3 for use in external circuit connection are installed in the circuit board 4, as shown in FIG. 2, the group of the terminals 3 formed as a single body via the connection body 9 is inserted into the circuit board 4 from its upper surface 4b so as to be in the state shown in FIG. 3. In other words, the first lead portion 3b and the second lead portion 3c of each terminal 3 are inserted through the first through-hole 4d and the second through-hole 4e corresponding thereto, respectively, and then the first lead portion 3b is soldered in the associated land portion 2b in a reflow manner. This reflow soldering step is performed by melting a cream solder (not shown) which is applied on the land portion 2b in the vicinity of the first through-hole 4d in a reflow furnace in advance; however, the short-sized first lead portion 3b does not protrude largely downwardly from the first through-hole 4d, and thereby the first lead portion 3b is reliably soldered in the land portion 2b. Thus, at this time, there is no concern about the solder being fixed to the second lead portion 3c. In addition, as shown in FIG. 4, the shield frame body 5 is installed in the circuit board 4, whereupon the lower cover 8 and the upper cover 7 are installed in the shield frame body 5, and thereby the electronic circuit unit 1 as shown in FIG. 6 is configured.

As described above, the electronic circuit unit 1 related to this embodiment has the first and second lead portions 3b and 3c which have lengths different from each other by substantially parallel extension of the terminal 3 for use in external circuit connection, and when this terminal 3 is installed in the circuit board 4, the short-sized first lead portion 3b is reliably soldered in the associated land portion 2b of the wire pattern 2 provided on the lower surface 4a of the circuit board 4. Therefore, it is not necessary to attach the solder to the long-sized second lead portion 3c spaced apart from the first lead portion 3b. Thereby, when the electronic circuit unit 1 is mounted on the motherboard 20, the second lead portion 3c of the terminal 3 can be easily inserted into the terminal installation hole 21 of the motherboard 20. In other words, the electronic circuit unit 1 adopts the terminal structure in which a poor soldering hardly occurs due to the bent form of the terminal 3 for use in external circuit connection, so the mounting intensity needed for providing the terminals can be easily obtained and also troublesome solder removal work can be omitted. Therefore, good mounting on the motherboard 20 can be easily achieved.

In the electronic circuit unit 1 related to this embodiment, the plurality of terminals 3 for external circuit connection, which are arranged in a row on the circuit board 4, are connected to each other in the state where the bridge connection portions 3a thereof are buried in the connection body 9 made of synthetic resins, so a relative position of this plurality of terminals 3 can be defined with high accuracy by the connection body 9 and further the plurality of terminals 3 can be treated as a single component at the time of mounting them on the circuit board 4. In addition, the connection body 9 can be stably mounted on the upper surface 4b of the circuit board 4, and thus it is possible to easily stabilize a position of the bridge connection portion 3a on the circuit board 4. Consequently, in this electronic circuit unit 1, the group of terminals 3 can be easily and also accurately mounted on the circuit board 4.

In the electronic circuit unit 1 related to this embodiment, the ground pattern 2a is adjacently disposed near the second through-hole 4e on the lower surface 4a of the circuit board 4, and thus the terminal 3 for external circuit connection is hardly influenced by external noises. Further, all of the second through-holes 4e for the group of terminals 3 are surrounded by the lateral plate 5b of the shield frame body 5 and the ground pattern 2a, and thus external noises are hardly introduced into each of the second lead portions 3c protruding downwardly from the vicinity of the one edge 4c of the circuit board 4. Therefore, the electronic circuit unit 1, in which the group of the terminals 3 is arranged in a row along the one edge 4c of the circuit board 4, has a high reliability.

Although the above-described embodiment has exemplified a television set tuner as the electronic circuit unit 1, the present invention is also applicable to an electronic circuit unit in which the terminal 3 for external circuit connection is soldered on the lower surface 4a of the circuit board 4, other than the television set tuner.

It should be understood by those skilled in the art that various modifications, combinations, sub-combinations and alterations may occur depending on design requirements and other factors insofar as they are within the scope of the appended claims of the equivalents thereof.

What is claimed is:

1. An electronic circuit unit electrically connected to a motherboard via a terminal soldered on a lower surface of a circuit board, comprising:
the terminal formed in a bent shape having a bridge connection portion disposed on an upper surface of the circuit board, a first lead portion extending downwardly from one end of the bridge connection portion so as to be inserted through a first through-hole of the circuit board, and a second lead portion extending downwardly longer than the first lead portion from the other end of the bridge connection portion so as to be inserted through a second through-hole of the circuit board,
wherein the first lead portion is soldered on the lower surface of the circuit board, and the second lead portion is inserted into a terminal installation hole of the motherboard when the electronic circuit unit is mounted on the motherboard.

2. The electronic circuit unit according to claim 1, wherein a plurality of terminals are arranged in a row on the circuit board, and a connection body made of synthetic resins is mounted on the circuit board, the connection body connecting the bridge connection portions of the plurality of terminals to each other in a buried state.

3. The electronic circuit unit according to claim 1, wherein the second through-hole is provided in the vicinity of one edge of the circuit board.

4. The electronic circuit unit according to claim 1, wherein a ground pattern is adjacently disposed near the second through-hole on the lower surface of the circuit board.

5. The electronic circuit unit according to claim 4, further comprising a metal shield frame body configured to contain and support the circuit board,
wherein the second through-hole is surrounded by a lateral plate of a shield frame body and a ground pattern.
